(19) United States
(12) Patent Application Publication
(10) Pub. No.: US 2026/0090063 A1
(43) Pub. Date: Mar. 26, 2026

(54) SEMICONDUCTOR STRUCTURE AND SEMICONDUCTOR DEVICE COMPRISING HIGH-K AMORPHOUS FLUORINATED CARBON ULTRATHIN FILM, AND METHOD FOR MANUFACTURING THE SAME

(71) Applicant: THE INDUSTRY & ACADEMIC COOPERATION IN CHUNGNAM NATIONAL UNIVERSITY (IAC), Daejeon (KR)

(72) Inventor: Eui-Tae KIM, Daejeon (KR)

(73) Assignee: THE INDUSTRY & ACADEMIC COOPERATION IN CHUNGNAM NATIONAL UNIVERSITY (IAC), Daejeon (KR)

(21) Appl. No.: 19/111,243

(22) PCT Filed: Jun. 13, 2023
(86) PCT No.: PCT/KR2023/008073

§ 371 Date: Mar. 12, 2025

(30) Foreign Application Priority Data
Sep. 15, 2022 (KR) 10-2022-0116327

(51) Int. Cl. H10D 64/62; H10D 64/01

(52) U.S. Cl. CPC H10D 64/62; H10D 64/011

(57) ABSTRACT

A semiconductor structure includes: a semiconductor material layer; a metal material layer; and an ultrathin film layer formed at the interface between the semiconductor material layer and the metal material layer, comprising amorphous fluorinated carbon having a dielectric constant of at least 10. The amorphous fluorinated carbon film further includes hydrogen trapped in dangling bonds in the amorphous carbon film.

### CROSS-REFERENCE TO PRIOR APPLICATIONS

This application is a National Stage Patent Application of PCT International Application No. PCT/KR2023/008073 (filed on Jun. 13, 2023), which claims priority to Korean Patent Application No. 10-2022-0116327 (filed on Sep. 15, 2022), which are all hereby incorporated by reference in their entirety.

### BACKGROUND

The present invention relates to a semiconductor structure and a semiconductor device comprising an amorphous fluorinated carbon ultrathin films having a high dielectric constant, low leakage current, and high dielectric strength, and to methods for manufacturing the same.

The gate length of metal oxide semiconductor field-effect transistors (MOSFETs), which are crucial in the fabrication of very large-scale integrated circuits (VLSI), has rapidly decreased from 10 μm to 10 nm over the past few decades. As the thickness of the SiO₂ gate dielectric decreases, gate tunneling current increases exponentially, causing excessive standby power in integrated circuits, thus the utility of SiO₂ thin films as a conventional insulating film has reached its limit. Therefore, with the integration of semiconductor devices such as memory devices and logic devices, development of high-k dielectrics with a high dielectric constant, low leakage current, and high dielectric strength is required to replace SiO₂ (k=3.9).

Materials having higher dielectric constants than SiO₂ are commonly referred to as high-k dielectrics. Ta₂O₄ and Al₂O₃ were initially applied as high-k materials, and since the adoption of sub-100 nm nodes in the late 2000s, alternative metal oxides such as ZrO₂ (k=25), HfO₂ (k=35), Al₂O₃ (k=10), and TiO₂ (k=41) have been extensively investigated to reduce gate leakage and power consumption. Currently, research is being conducted in various directions, such as identifying alternative materials to replace Hf sources (Al, Zr, Ta, STO, BST, etc.) or developing deposition methods that incorporate additional materials with Hf sources.

These high-k dielectrics can mostly be applied to devices in the form of oxide thin films. However, the high-k layer of metal oxides contains numerous bulk traps such as oxygen vacancies, increasing CV hysteresis and causing threshold voltage instability.

Furthermore, as the device node size shrinks to the 10 nm scale, an equivalent oxide thickness (EOT) of 1 nm or less is required, and under these conditions, electron tunneling can occur in Hf- or Zr-based oxides. Moreover, oxides Hf-based are prone to crystallization due to their low crystallization temperature, exhibit thermal instability when in contact with Si, and have a high defect density. Zr-based oxides have high film crystallinity, resulting in a rough surface and a high density of grain boundaries, leading to very high leakage current. Ti-based oxide films inherently have a low bandgap energy of 3.5 eV, causing problems due to high leakage current and low dielectric strength. Therefore, for the development of devices with sub-10 nm nodes, the application of a novel high-k dielectric material with low leakage current and high dielectric strength is required.

Organic electronic devices have drawn significant attention due to their potential as large-area, low-cost, and flexible devices. Most organic materials are either amorphous or poorly crystalline, exhibiting smooth surfaces. Among organic materials, carbon is the most versatile material, and carbon thin films are receiving considerable attention in technical and industrial applications due to their excellent electrical and mechanical properties. The electrical properties of materials are directly related to their structure, and the key to the diversity of carbon-based materials also lies in their chemical bonding. σ-bonds between sp³ state carbon atoms generally exhibit insulating properties. Diamond is a strong insulator (conductivity <10⁻¹⁵ Ω⁻¹ cm⁻¹) and is extremely hard because its carbon atoms are only connected by sp³ bonds. On the other hand, in the presence of n-bonds associated with groups of carbon atoms in the sp² state, electrons are delocalized and can be used as charge carriers. Graphite has sp² bonds and, unlike diamond, exhibits high conductivity (10⁴ Ω⁻¹ cm⁻¹).

It is well known that the bonding of carbon materials can be controlled by adjusting the deposition temperature during the manufacture of carbon thin films. Notably, chemical vapor deposition (CVD) is a widely used technique for fabrication of carbon thin films, capable of producing high-quality graphene and carbon nanotubes at high temperatures of approximately ˜1000° C. When the deposition temperature is lowered to about 700° C. during CVD, nanographite structures are formed, and amorphous carbon is formed at room temperature. Research on carbon-based materials has focused particularly on nanostructures with highly aligned structures, such as graphene and carbon nanotubes, which have high potential as transparent conductors or next-generation semiconductors due to their high conductivity characteristics and transparency. As a result, despite nanographite and amorphous carbon also exhibiting several interesting characteristics, attempts to develop materials with new properties utilizing these and to apply them have received relatively little attention.

As nanographite and amorphous carbon contain a considerable proportion of so-called “dangling bonds”, which are fixed free radicals, they form amorphous hydrogenated carbon films by reacting with hydrogen and/or HC radicals under appropriate conditions. However, attempts to develop and apply materials with new properties by utilizing dangling bonds in nanographite or amorphous carbon have been limited. In the prior art, amorphous hydrocarbon films were limited to use as etching masks due to the ease of forming thin films of uniform thickness, or as low-k dielectric materials such as interlayer materials for semiconductor metal wiring to prevent thin film defects and increase interlayer adhesion.

Similar to amorphous hydrogenated carbon films, amorphous fluorinated carbon (a-C:Fs) films can be formed in the presence of fluorine and/or FC (fluorocarbon) radicals. Korean Patent No. 10-0283007 reports that when manufacturing amorphous fluorinated carbon by increasing fluorine concentration in amorphous carbon, the permittivity can be further lowered compared to amorphous hydrogenated carbon. Accordingly, amorphous fluorinated carbon films have been mainly reported to be used as insulating films (Korean Patents No. 10-0427508, No. 10-0283007, Japanese Patent No. 3666106) utilizing their low permittivity characteristics, and there have been no reports on amorphous fluorinated carbon films having high-k properties.

### SUMMARY

The present invention aims to solve the problems of the prior art by providing a semiconductor structure comprising a novel high-k amorphous fluorinated carbon ultrathin film having a high dielectric constant, low leakage current and high dielectric strength, which makes it useful for manufacturing highly integrated devices, and to a semiconductor device and a method for manufacturing the same.

To achieve the aforementioned objectives, the present invention relates to a semiconductor structure characterized in that it comprises: a semiconductor material layer; a metal material layer; and an ultrathin film layer formed at the interface between the semiconductor material layer and the metal material layer, comprising amorphous fluorinated carbon having a dielectric constant of at least 10.

Throughout the specification, when any part “comprises” any component, unless specifically stated otherwise, this means that other components are not excluded but may be further included. Also, when any part such as a layer, film, region, or plate is “on” or “above” another part, this includes not only cases where it is “directly on” the other part but also cases where other parts exist in between. Conversely, when any part is “directly on” another part, it means there are no other parts in between. Furthermore, when any part is formed “entirely” on another part, this includes not only cases where it is formed on the entire surface of the other part but also cases where it is not formed on some edges.

In this specification, “amorphous” is a term used in contrast to “crystalline,” indicating the absence of long-range order in atomic positions. That is, the “amorphous” thin film of the present invention may be composed entirely of an amorphous phase, but may include nano-crystalline regions having short-range order. In the amorphous fluorinated carbon thin film of the present invention, the bonding between carbon atoms may include both sp² and sp³ bonds, but the ratio thereof does not limit the thin film of the present invention.

Furthermore, in this specification, the term “amorphous fluorinated carbon thin film” refers to an amorphous carbon thin film containing fluorine trapped in dangling bonds, and does not exclude the presence of other elements trapped by dangling bonds. For example, the amorphous fluorinated carbon thin film of the present invention may further comprise hydrogen trapped by dangling bonds. In the thin film, fluorine may be bonded in the form of —CF, —CF₂, or —CF₃.

According to the prior art, amorphous carbon thin films were known to be low-k thin films with very low dielectric constants, and when fluorine was incorporated into amorphous carbon thin films, the permittivity was known to decrease further. The semiconductor structure of the present invention is characterized in that it comprises an amorphous fluorinated carbon ultrathin film, unlike conventional amorphous fluorinated carbon films, exhibiting high-k dielectric characteristics at the interface between the semiconductor material layer and the metal material layer. In the present invention, the amorphous fluorinated carbon ultrathin film is characterized by having a dielectric constant of 10 or more, preferably 40 or more, which surpasses the dielectric constants of conventional Hf-based, Zr-based, or Ti-based oxide films, and more preferably 60 or more.

In the semiconductor structure of the present invention, the amorphous fluorinated carbon thin film has very low surface roughness due to its amorphous structure, with an rms surface roughness of 5 nm or less, preferably 3 nm or less, and more preferably 2 nm or less. Due to the low surface roughness, an ultrathin film with a thickness of 10 nm or less can be formed without pinholes, and low leakage current and high dielectric strength characteristics can be achieved.

While conventional high-k materials are difficult to apply to devices with nodes of 10 nm or less due to high leakage current, low dielectric strength, and high CV hysteresis characteristics, the high-k amorphous fluorinated carbon thin films not only have high dielectric constant values but also exhibit excellent electrical characteristics. Based on an equivalent oxide thickness of 0.1 nm, the amorphous fluorinated carbon ultrathin film of the present invention has a leakage current of 10 A/cm² or less at an applied voltage of 1 V, a dielectric strength of 10 MV/cm or more, and a CV hysteresis of 5 mV or less, making it useful even in devices with nodes of 10 nm or less.

In metal-semiconductor junctions, there is an issue of non-ideal Schottky barrier formation due to the Fermi level pinning phenomenon at the interface between the semiconductor material layer and the metal material layer. This acts as a parasitic resistance, thereby reducing electron injection efficiency and consequently causing device performance degradation. In the semiconductor structure of the present invention, the high-k amorphous fluorinated carbon ultrathin film layer formed at the interface between the semiconductor material layer and the metal material layer removes the Fermi level pinning phenomenon, enabling efficient electron injection and thereby allowing excellent performance. It was confirmed that electrical connection between the semiconductor material layer and the metal material layer is possible through the ultrathin film layer, which is believed to be due to electron movement by the tunneling effect as the amorphous fluorinated carbon, although being an insulating material, is formed as an atomic-scale ultrathin film with a thickness of less than 10 nm. Furthermore, the ultrathin film layer can serve to suppress dangling bonds included in the semiconductor material layer.

In the semiconductor structure of the present invention, the amorphous fluorinated carbon ultrathin film layer can be formed by: (A) placing a substrate composed of a semiconductor material or a substrate having a semiconductor material layer formed thereon in a plasma reactor; (B) introducing a first gas comprising fluorocarbon gas and a second gas comprising an inert gas into the reactor; and (C) generating plasma in the reactor; wherein at least one of the temperature of the reactor, pressure, flow rate of the first gas, flow rate of the second gas, and plasma intensity is controlled to grow an amorphous thin film having a dielectric constant of 10 or more.

In the present invention, a plasma reactor refers to one that induces the reaction of reaction gases by generating plasma in the reactor, examples of which include plasma-enhanced chemical vapor deposition (PE-CVD), inductively coupled plasma chemical vapor deposition (ICP-CVD), or electron cyclotron resonance chemical vapor deposition (ECR-CVD) reactors. Plasma generates a large amount of highly reactive radicals from reaction gases, enabling thin film formation even at low temperatures. Although ICP-CVD is provided as an example in the following embodiments, the invention is not limited thereto.

In the present invention, the substrate may itself be composed of a semiconductor material, or may have a semiconductor material layer formed on a conventional substrate for manufacturing semiconductor structures, such as a glass or metal oxide substrate. In the case of a substrate having a semiconductor material layer formed thereon, a separate active layer may be formed on the entire substrate or a portion thereof below the semiconductor material layer. According to the present invention, since no separate catalyst layer is required for growing the amorphous fluorinated carbon ultrathin film, the amorphous fluorinated carbon ultrathin film can be directly deposited on the semiconductor material layer without undergoing a separate transfer process. However, this does not exclude forming the ultrathin film layer by growing the amorphous fluorinated carbon ultrathin film on a separate substrate and then transferring it onto the semiconductor material layer. Furthermore, since film growth is possible at temperatures below 400° C. or less, it can be achieved without substrate damage even in case including polymer substrates such as polyimide.

The manufacturing method of the present invention may further comprise a step of cleaning the substrate prior to step (A). The substrate cleaning can be performed using an appropriate method depending on the type of substrate material, and through this substrate cleaning step, not only does it create a surface condition conducive to thin film growth, but it also reduces interfacial defects with the grown thin film, resulting in excellent interfacial properties.

The characteristics of the amorphous fluorinated carbon ultrathin film constituting the high-k dielectric film are determined by the temperature of the reactor, pressure, flow rate of the first gas, flow rate of the second gas, and plasma intensity, and by controlling each variable, an amorphous fluorinated carbon ultrathin film having a dielectric constant of 10 or more can be grown. Each variable is described in detail below. Naturally, the optimized absolute values of each variable may vary depending on the specific equipment used, and by referring to the following description of variables, it will be possible to manufacture a thin film with an appropriate thickness, dielectric constant, and surface roughness for the intended use.

The first gas comprises a fluorocarbon gas. Any fluorocarbon gas that can be used to form a fluorinated carbon thin film via plasma can be used, and carbon-based compounds commonly used for graphene manufacture by chemical vapor deposition at high temperatures, for example, compounds selected from the group consisting of methane, ethane, propane, ethylene, acetylene and propylene, wherein hydrogen is substituted with fluorine, can be used. The substitution of hydrogen with fluorine includes not only complete substitution of all hydrogen atoms in the compound but also partial substitution of hydrogen with fluorine. For example, compounds wherein the hydrogen in methane is substituted with fluorine include not only CF₄ used in the examples but also CHF₃, CH₂F₂ and CH₃F. When the fluorocarbon contains hydrogen atoms, hydrogen along with fluorine can be trapped by dangling bonds in the thin film. Also, this does not exclude fluorocarbon compounds other than the compounds mentioned above.

The second gas comprises an inert gas and acts as a carrier gas that controls the pressure in the reactor and the concentration of fluorocarbon. The second gas may further comprise hydrogen. Even when hydrogen is present in the second gas, hydrogen can be trapped along with fluorine by dangling bonds. Therefore, when hydrogen is present in the second gas, the ratio of fluorine and hydrogen trapped by dangling bonds in the thin film can be controlled by adjusting the volume ratio of the fluorocarbon gas in the first gas and the hydrogen gas in the second gas. The volume ratio of fluorocarbon gas in the first gas to the hydrogen gas in the second gas can be set to 100:0 to 1:50. It is natural that as the volume ratio of hydrogen gas increases, the ratio of hydrogen to fluorine trapped by dangling bonds increases, and if the volume ratio of hydrogen gas to fluorocarbon gas exceeds 1:50, the trapping ratio of fluorine may become too low.

The volume ratio of the first gas to the second gas may be, for example, 1:1 to 1:100. If the ratio of the second gas is too high compared to the first gas, the thin film growth may be too slow or may become difficult, and if the ratio of the second gas is too low, the film surface may become rough, degrading the surface characteristics.

When plasma is applied in the presence of fluorocarbon gas, a fluorinated carbon thin film is formed on the substrate. It is already well known that during the deposition of carbon thin films using carbon gas, high-quality graphene films are formed at high temperatures above 900° C., and as the temperature decreases, dangling bonds increase and the crystallinity of the graphene film decreases. In the manufacture of the thin film of the present invention, the characteristics of the resulting thin film also changed depending on the temperature of step (C). At high temperatures, graphene is formed, and as the temperature decreases, nano-graphite containing nano-graphene crystals in the amorphous thin film is formed, and when the thin film manufacturing temperature is further lowered, the high-k amorphous fluorinated carbon thin film of the present invention is formed. Although the high-k characteristics of thin films manufactured at room temperature to 400° C. are described in the following embodiments, since they may vary depending on other reaction conditions such as the equipment used, fluorocarbon gas concentration, pressure in the reactor, and plasma intensity, restricting them to specific values is meaningless, and considering various conditions, it is preferable to control the reaction temperature within the range of 20 to 700° C.

In step (C), the pressure in the reactor is preferably between 0.1 and 10 Torr to ensure smooth plasma discharge. If the pressure is too high, it is difficult to maintain the plasma, resulting in reduced thin film deposition efficiency, and if the pressure is too low, the process efficiency decreases.

The plasma intensity also affects the properties of the resulting thin film. Preferably, the intensity of the plasma is controlled in the range of 100 W to 1,000 W. As the intensity of the plasma increases, the growth rate of the thin film increases, the surface roughness decreases, and the dielectric constant tends to increase (data not shown), therefore intensities above 1,000 w are not excluded. Furthermore, when the plasma intensity is low, the thickness or surface roughness of the thin film can be controlled by increasing the deposition time, and the dielectric constant may also change accordingly. Therefore, plasma intensities below 100 W are not excluded either.

The optimal temperature, pressure, flow rate of the first gas, flow rate of the second gas, and plasma intensity of the reactor are factors that influence each other, so even if one variable exhibits an optimal value at a specific value when other variables are fixed, it is natural that its absolute value may change as other variables are adjusted.

The present invention confirms the characteristics of amorphous fluorinated carbon thin films whose high-dielectric properties have not been known until now, and aims to apply them in the form of an ultrathin film to semiconductor structures, and it will be easy for those skilled in the art to design them by varying the conditions to achieve optimal characteristics, including desired thickness, dielectric constant, and surface roughness, depending on the design of other components constituting the semiconductor structure.

Another aspect of the present invention relates to a semiconductor device utilizing the above high-k amorphous fluorinated carbon film, specifically, to a semiconductor device comprising source/drain regions a and contact structure electrically connected to the source/drain regions, wherein an amorphous fluorinated carbon ultrathin film layer having a dielectric constant of 10 or more is interposed between the source/drain regions and the contact structure. As in the aforementioned semiconductor structure, in the semiconductor device of the present invention, the high-k amorphous fluorinated carbon ultrathin film layer formed at the interface between the semiconductor material layer and the metal material layer removes the Fermi level pinning phenomenon, enabling efficient electron injection and thereby allowing the semiconductor device to exhibit excellent performance. Furthermore, the ultrathin film layer can serve to heal dangling bonds included in the source/drain regions. As exemplified in the following embodiments,
i) The semiconductor device may comprise:
a substrate;
source/drain regions arranged facing each other on the substrate;
a gate electrode disposed on the substrate for applying an electric field;
a gate dielectric film interposed between the gate electrode and the substrate; and
a contact structure electrically connected to the source/drain regions,
according to the present invention.
ii) Alternatively, the device may comprise:
a substrate;
a fin-type active region extending in a first direction on the substrate;
a gate structure extending in a second direction intersecting with the fin-type active region on the substrate, comprising a gate electrode and a gate dielectric film;
source/drain regions disposed on both sides of the gate structure; and
a contact structure electrically connected to the source/drain regions,
according to the present invention.
iii) In another embodiment, the device may comprise:
a substrate;
a fin-type active region protruding from the substrate and extending in a first direction;
a plurality of semiconductor patterns spaced apart from each other on the upper surface of the fin-type active region and having channel regions;
a gate electrode surrounding the plurality of semiconductor patterns and extending in a second direction perpendicular to the first direction, comprising a main gate electrode disposed at the uppermost part of the plurality of semiconductor patterns and extending in the second direction, and sub-gate electrodes disposed between the plurality of semiconductor patterns;
a gate dielectric film disposed between the gate electrode and the plurality of semiconductor patterns;
spacers disposed on both sidewalls of the main gate electrode;
source/drain regions disposed on both sides of the gate electrode, connected to the plurality of semiconductor patterns and in contact with the lower surface of the spacers; and
a contact structure electrically connected to the source/drain regions,
according to the present invention.

It should be understood, however, that these are illustrative embodiments of specific configurations of the semiconductor device of the present invention and are not limited thereto.

As described above, the semiconductor structure of the present invention comprises a high-k amorphous fluorinated carbon ultrathin film that exhibits remarkably higher dielectric values than not only SiO₂ but also conventional Hf- or Zr-based oxides while maintaining very low leakage current and high dielectric strength characteristics, preventing Fermi level pinning phenomenon, improving electron injection efficiency by suppressing dangling bonds in the semiconductor material layer, and can thus be more effectively utilized in implementing semiconductor devices with nodes of 10 nm or less.

Furthermore, since the high-k amorphous fluorinated carbon ultrathin film in the semiconductor structure of the present invention does not require a catalyst layer during manufacture, it can be deposited directly onto the desired substrate without requiring a transfer process, resulting in excellent interfacial characteristics that can improve semiconductor device performance. Additionally, since high-k film formation is possible even at low temperatures below 400° C., it can be applied to flexible devices that are vulnerable to heat.

### BRIEF DESCRIPTION OF THE DRAWINGS

FIG. 1 shows Raman spectra of thin films grown at different deposition temperatures.

FIG. 2 shows an AFM image of an amorphous fluorinated carbon thin film.

FIG. 3 shows IR spectra of thin films according to deposition temperatures.

FIG. 4 shows XPS spectra of thin films according to deposition temperatures.

FIG. 5 shows C-V curves of amorphous fluorinated carbon thin films according to deposition temperatures.

FIG. 6 is an HR-TEM image showing the interface between the Si substrate and the amorphous fluorinated carbon thin film.

FIG. 7 is graphs showing the thickness and dielectric constant of thin films as a function of deposition temperature.

FIG. 8 shows a J-V curves of amorphous fluorinated carbon thin films according to deposition temperatures.

FIG. 9 is a cross-sectional view illustrating the structure of a semiconductor structure of the present invention utilizing a high-k amorphous fluorinated carbon film.

FIG. 10 is a cross-sectional view illustrating a semiconductor device according to an embodiment of the present invention utilizing a high-k amorphous fluorinated carbon film.

FIG. 11 is a layout view and cross-sectional view illustrating a semiconductor device according to an embodiment of the present invention utilizing a high-k amorphous fluorinated carbon thin film.

FIG. 12 is a cross-sectional view illustrating a semiconductor device according to an embodiment of the present invention utilizing a high-k amorphous fluorinated carbon thin film.

### DETAILED DESCRIPTION

The present invention will now be described in more detail with reference to the accompanying drawings and exemplary embodiments. However, these drawings and examples are merely illustrative to facilitate explanation of the technical content and scope of the present invention, and the technical scope of the present invention is neither limited nor altered thereby. It would be apparent to those skilled in the art that various modifications and variations are possible within the scope of the technical concept of the present invention based on these examples.

### EXAMPLE

### Example 1: Preparation of Amorphous Fluorinated Carbon Thin Films

Under the following conditions, fluorinated carbon thin films were deposited on an n-type crystalline Si(100) substrate using CF₄ gas and a hydrogen/argon mixture by inductively-coupled plasma chemical vapor deposition (ICP CVD). Specifically, 10 sccm of CF₄ gas and 100 sccm of hydrogen/argon gas mixture (10% hydrogen) were individually introduced into the reactor. The Si substrate was cleaned by standard cleaning methods, first with a 10% HF solution for 30 s and then washed with DI water. During deposition, the pressure was fixed at 1 Torr, plasma power at 400 W, and deposition time at 30 min, while the deposition temperature was controlled in the range from room temperature to 400° C. to examine the effects of deposition temperature.

### Example 2: Characterization of Carbon Thin Films as a Function of Deposition Temperature

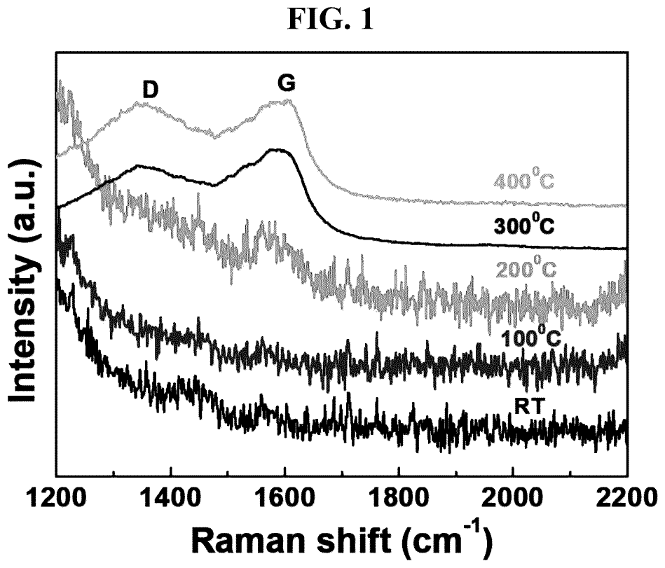

Raman spectra were observed for thin films formed at different deposition temperatures, and the results are shown in FIG. 1. The Raman spectra of samples deposited at low temperatures of room temperature or 100° C. showed only the G band at 1575 cm⁻¹, indicating the formation of completely disordered amorphous fluorinated carbon (a-C:F) thin films consisting mostly of disordered six-membered rings or rings of different orders and almost completely sp²-bonded. In the sample deposited at 200° C., the intensity of the G peak increased significantly, and as the deposition temperature was further increased to 300° C. and 400° C., the G peak shifted from 1575 cm⁻¹ to 1599 cm⁻¹, and a new D peak was observed, indicating graphitization of the amorphous carbon thin film. The appearance of the D peak indicates that the amorphous carbon is ordered but has a disordered structure of graphite. The appearance of the D peak and the shift of the G peak suggest a decrease in the sp³/sp² ratio, and it was expected that the dielectric properties of the amorphous fluorinated carbon thin film could be controlled through changes in the sp³/sp² ratio.

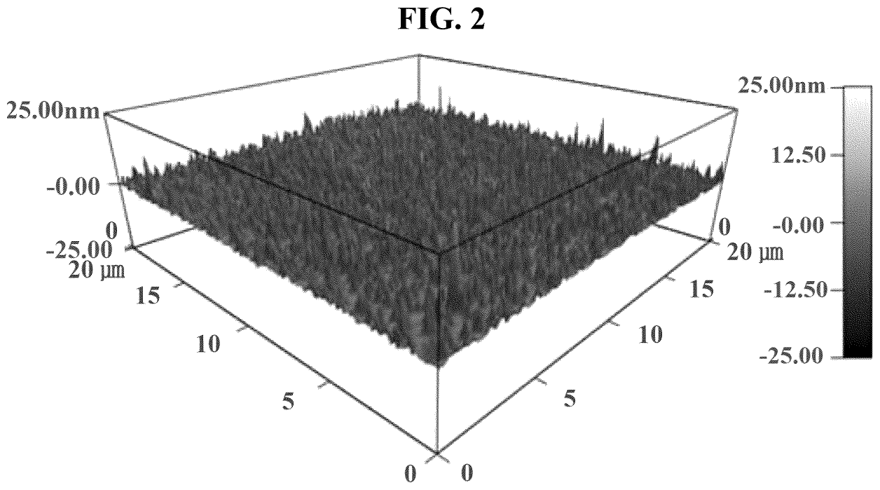

FIG. 2 is an AFM (Asylum Research, MFP-3D) image of an amorphous fluorinated carbon thin film grown directly on a Si substrate, confirming a uniform, pinhole-free and smooth thin film was grown. The thin film had a surface roughness (root-mean-square roughness) value of 1.4 nm.

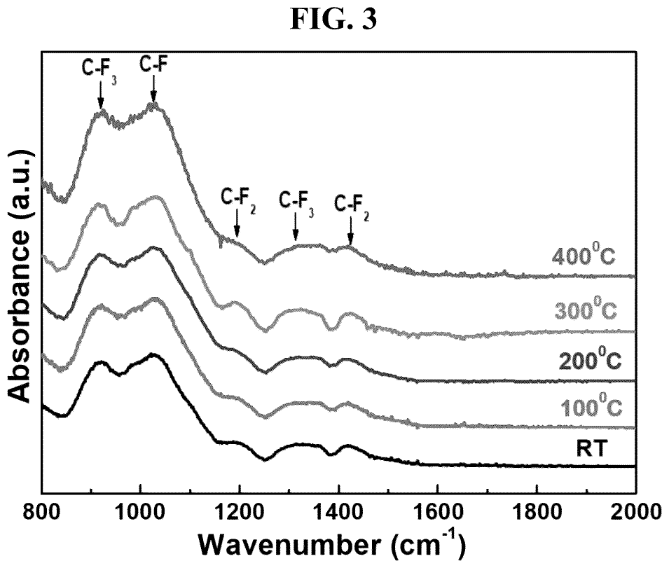

The chemical structure of the resulting amorphous fluorinated carbon thin films was confirmed by FTIR (Nicolet 6700 Fourier transform infrared spectrometer). FIG. 3 shows the IR spectra of the thin films according to deposition temperature, with all the films showing similar spectra regardless of the growth temperature. The strong peak at 1030 cm⁻¹ is attributed to the asymmetric stretching of F atoms along the direction parallel to the C—F bond. The absorption bands at 923 cm⁻¹ and 1314 cm⁻¹ are attributed to C—F₃ stretching, and the absorption bands at 1192 cm⁻¹ and 1314 cm⁻¹ are attributed to symmetric and asymmetric stretching of C—F₂. Therefore, the FTIR spectra confirmed the presence of C—F, C—F₂, and C—F₃ bonds in all the films produced at each temperature, and thus the films produced are amorphous fluorinated carbon thin films with fluorine trapped in the dangling bonds.

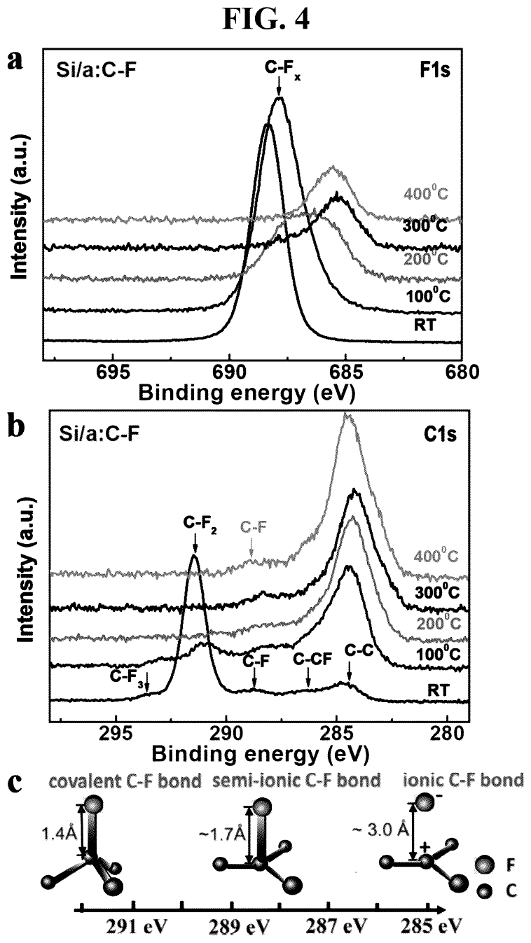

The chemical bonding in the thin films was further confirmed by XPS (K-Alpha X-ray photoelectron spectrometer) measurements. As shown in FIG. 4a, the peak position for C—Fₓ bonds in the Fis spectrum shifted to lower energy from 688.3 eV to 685.4 eV as the F/C ratio decreased with increasing growth temperature of the thin film. In particular, the XPS spectra showing Cis binding energy shown in FIG. 4b exhibited significant variations depending on the thin film growth temperature. In the XPS spectrum of the thin film deposited at room temperature, the peaks for C—F, C—F₂, and C—F₃ bonds were dominant, but when the deposition temperature increased to 100° C., the C—C peak increased dramatically, while the C—F peak gradually increased whereas the C—F₂ and C—F₃ peaks decreased significantly. As the deposition temperature further increased to 200, 300, and 400° C., peaks due to C—C and C—F bonds became predominant. As shown in FIG. 4c, C—F bonds have the longest bond length of 3.0 Å compared to C—F₂ bonds (1.7 Å) or C—F₃ bonds (1.4 Å). Therefore, the predominance of C—F bonds in the amorphous fluorinated carbon thin film is expected to enhance both the dipole moment and the dielectric characteristics of the thin film.

### Example 3: Evaluation of Electrical Properties of Amorphous Fluorinated Carbon Thin Films

An MIS device utilizing the amorphous fluorinated carbon thin film of the present invention as a dielectric layer was fabricated, and the electrical properties of the amorphous fluorinated carbon thin film were evaluated. Specifically, an MIS device was fabricated by forming circular Ti (5 nm)/Au (200 nm) electrodes by DC sputtering on the amorphous fluorinated carbon thin film grown on a Si substrate following the method described in Example 1.

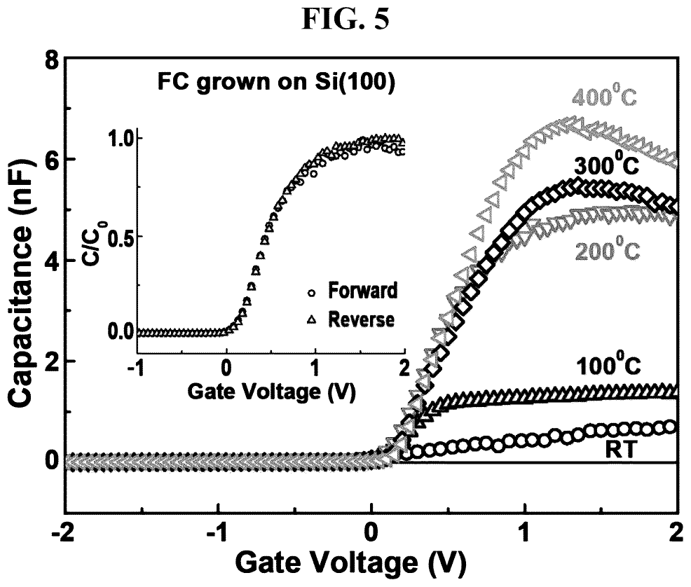

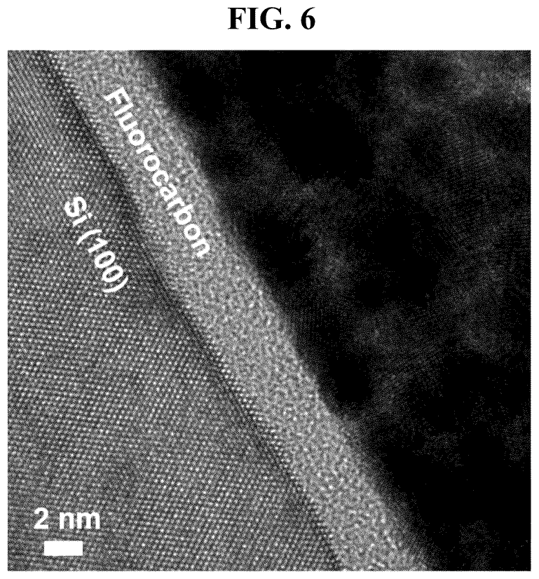

FIG. 5 shows the C-V curves of the amorphous fluorinated carbon thin film measured from the fabricated MIS device, showing a significant increase in capacitance as the film growth temperature increases. In the inset graph, o represents values measured in the forward direction from −2 V to 2 V, and Δ represents values measured in the reverse direction from +2 V to −2 V. The hysteresis in the C-V loops for all samples showed values close to zero (<5 mV). Extremely small hysteresis indicates that the trapped charge density at the interface between the amorphous fluorinated carbon thin film and the Si substrate is very low. The excellent interfacial characteristics can be explained by (i) the formation of fluorinated dangling bonds at the Si interface during the growth of the amorphous fluorinated carbon thin film by ICP-CVD and (ii) the absence of an interfacial oxide layer between Si and the amorphous fluorinated carbon layer, as confirmed by the HR-TEM image in FIG. 6.

The dielectric constant of an amorphous fluorinated carbon thin film can be calculated from the C-V curves using the following equation.

$$k = d {C}_{max} / {ε}_{0} A$$

where k is the dielectric constant, d is the thickness of the film, Cₘₐₓ is the accumulation capacitance, ε₀ is the permittivity in vacuum, and A is the area of the MIS device.

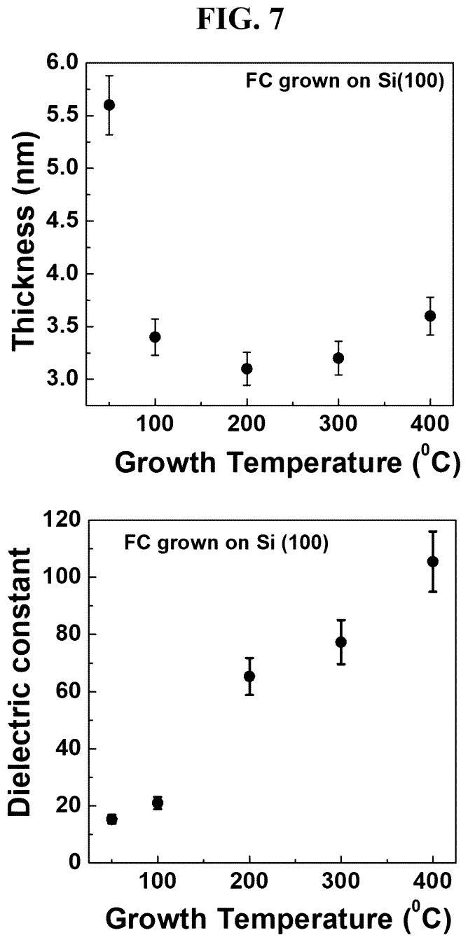

The upper graph in FIG. 7 shows the thickness of amorphous fluorinated carbon thin films grown at each deposition temperature measured using an ellipsometer M-2000, indicating that the film grown at room temperature had a thickness of 5.5 nm while films grown at 100-400° C. had a thickness ranging from 3 to 3.5 nm. The dielectric constant calculated from the film thickness was plotted against deposition temperature and is shown in the lower part of FIG. 7. The dielectric constant increased slightly for the thin film deposited at 100° C. compared to the thin film deposited at room temperature, but showed a sharp increase at deposition temperatures of 200° C. and above. These results are consistent with the Raman and XPS spectra shown in FIGS. 1 and 3. The dielectric constant of the amorphous fluorinated carbon thin film grown at 400° C. was 105, which demonstrates a significantly higher permittivity than not only the previously reported dielectric constants of 20-30 for Hf- and Zr-based oxides but also the dielectric constant of 90 for the amorphous carbon thin film reported by the present inventors in Korean Patent No. 10-2314727 and others.

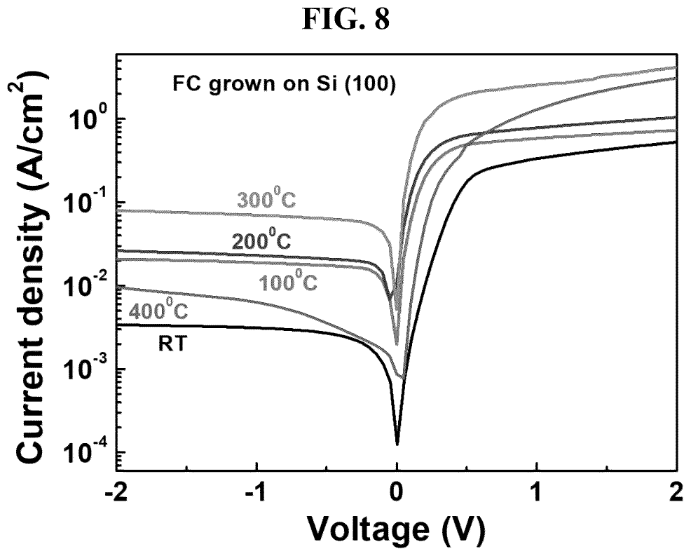

An important requirement for high-k dielectrics is low leakage current density and high dielectric strength. To verify the practical utility of the amorphous fluorinated carbon thin film as a gate dielectric material, J-V measurements were conducted and the results are shown in FIG. 8. The amorphous fluorinated carbon thin film grown at 400° C., which exhibited the highest permittivity with a dielectric constant of 105, demonstrated an excellent MIS leakage current density of approximately 5 A/cm² at an applied voltage of 1V for an equivalent oxide thickness (EOT) of 0.1 nm. Furthermore, no breakdown phenomenon was observed up to 3V, the voltage applied for J-V measurements, confirming that the dielectric strength has a high value of at least 10 MV/cm. These leakage current and dielectric strength values are at least comparable to, if not superior to, those of recently reported high-k oxides.

### Example 4: Implementation Examples of a Semiconductor Structure and Semiconductor Devices

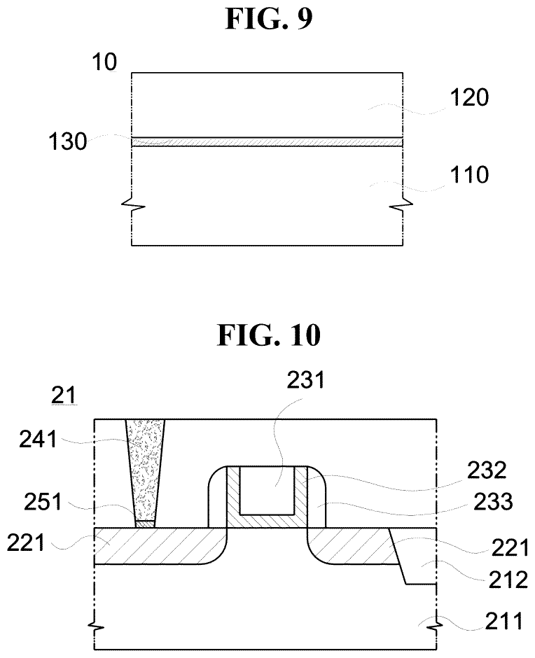

In this embodiment, the semiconductor structure and semiconductor devices of the present invention are described with reference to FIGS. 9 to 12. However, those skilled in the art to which the present invention pertains will understand that the semiconductor device of the present invention may be implemented in other specific forms without altering its technical concept or essential characteristics. Therefore, the following embodiments should be understood in all aspects as exemplary and not limiting. Hereinafter, when it is determined that detailed descriptions of known technologies related to the invention may unnecessarily obscure the essence of the invention, such descriptions will be omitted.

FIG. 9 illustrates a semiconductor structure (10) comprising a semiconductor material layer (110), a metal material layer (120), and an ultrathin film layer (130). In heterojunction structures of semiconductor material layers and metal material layers, Fermi level pinning occurs due to interfacial defects. This results in the formation of a non-ideal Schottky barrier between the semiconductor material and the metal material layer, hindering ohmic contacts, thereby reducing electron injection efficiency at the interface d causing device performance degradation.

In the semiconductor structure of the present invention, the aforementioned high-k amorphous fluorinated carbon ultrathin film layer formed at the interface between the semiconductor material layer and the metal material layer can achieve ideal and efficient electron injection efficiency by eliminating the Fermi level pinning phenomenon at the interface between the semiconductor material layer and the metal material layer. It was confirmed that electrical connection between the semiconductor material layer and the metal material layer is possible through the high-k amorphous fluorinated carbon, which is a high-k insulating material, which is believed to be due to electron movement by tunneling phenomenon as it is formed as an ultrathin film with atomic-scale thickness of less than 10 nm.

Furthermore, in the semiconductor structure of the present invention, the ultrathin film layer can serve to suppress dangling bonds included in the semiconductor material layer. Unlike the bulk state, there are unpaired dangling bonds on the surface of the semiconductor material layer, which leads to deterioration of interface characteristics such as Fermi level pinning phenomenon during heterojunction with the metal material layer. In the present invention, fluorine or carbon bonds with dangling bonds during the growth of the ultrathin film layer, thereby healing them and enabling superior interface characteristics.

The semiconductor structure of the present invention can be used in a device comprising a heterojunction of a semiconductor material and a metal, such as a semiconductor device comprising a source/drain regions comprising a semiconductor material layer and a contact structure comprising a metal material layer, to improve the performance of the device by eliminating the Fermi level pinning phenomenon.

FIGS. 10 to 12 show cross-sectional views of exemplary semiconductor devices of the present invention wherein an amorphous fluorinated carbon ultrathin film layer having a dielectric constant of 10 or more is interposed between the source/drain regions and the contact structure.

First, FIG. 10 illustrates a semiconductor device (21) comprising a substrate (211), source/drain regions (221), a gate electrode (231), a gate dielectric film (232), and a contact structure (241).

The substrate (211) may be any one of a variety of substrates used in conventional semiconductor device processes, such as glass, plastic, or a silicon substrate. In some embodiments, the substrate (211) may be composed of semiconductors such as silicon (Si) and germanium (Ge), or compound semiconductors such as SiGe, SiC, GaAs, InAs, InP. In other embodiments, the substrate may have a silicon-structure. In still other embodiments, the on-insulator (SOI) substrate may have other active layers formed on its surface.

The substrate may further comprise active regions defined by a device isolation film (212). The device isolation film may be a single insulating film, but may also include external and internal insulating films. The external and internal insulating films may be formed of the same material or different materials. For example, the external insulating film may be formed of an oxide film and the internal insulating film may be formed of a nitride film, but is not limited thereto.

The substrate comprises source/drain regions (221) disposed opposite each other, defining a channel region between them. The source/drain regions may be formed within the substrate or may be formed by protruding from the substrate.

The gate electrode (231) is disposed on the substrate to apply an electric field to the channel region. The gate electrode may comprise a single gate film or may be formed from multiple films. In some embodiments, the gate electrode (231) may comprise at least one material selected from the group consisting of doped semiconductors, metals, conductive metal or metal nitrides, silicides.

A gate dielectric film is interposed between the gate electrode (231) and the substrate (211). The gate dielectric film may be formed of a low-k material film or a high-k material film. For example, it may be composed of a material selected from silicon oxide film, silicon oxynitride film, hafnium oxide film, zirconium oxide film, tantalum oxide film, and titanium oxide film, or an amorphous fluorinated carbon film having a dielectric constant of 10 or more, but is not limited thereto. In FIG. 10, while the gate dielectric film is shown as being formed on both the bottom and sides of the gate electrode, it may be formed only on the bottom of the gate electrode.

Spacers (233) may additionally be formed on the sides of the gate electrode and the gate dielectric film. The spacers may be formed of at least one of silicon oxide, silicon nitride, and silicon oxynitride. While FIG. 10 shows the spacers as being formed in a single layer, it is apparent that they are not limited thereto and may be formed in multiple layers.

The contact structure (241) is arranged to be electrically connected to the source/drain regions. In some embodiments, the contact structure may be referred to as source/drain contacts. The contact structure may be formed of one or more selected from conductive metal films, metal nitride films, metal oxide films, metal oxynitride films, and doped semiconductor materials.

In the semiconductor device of the present invention, a high-k amorphous fluorinated carbon ultrathin film layer (251) having a dielectric constant of 10 or more is interposed between the source/drain regions and the contact structure. While the amorphous fluorinated carbon is a high-k insulating material with low leakage current density and high dielectric strength, electrical connection between the source/drain regions and the contact structure is possible through tunneling phenomenon as the ultrathin film layer is formed with atomic-scale thickness of 10 nm of less.

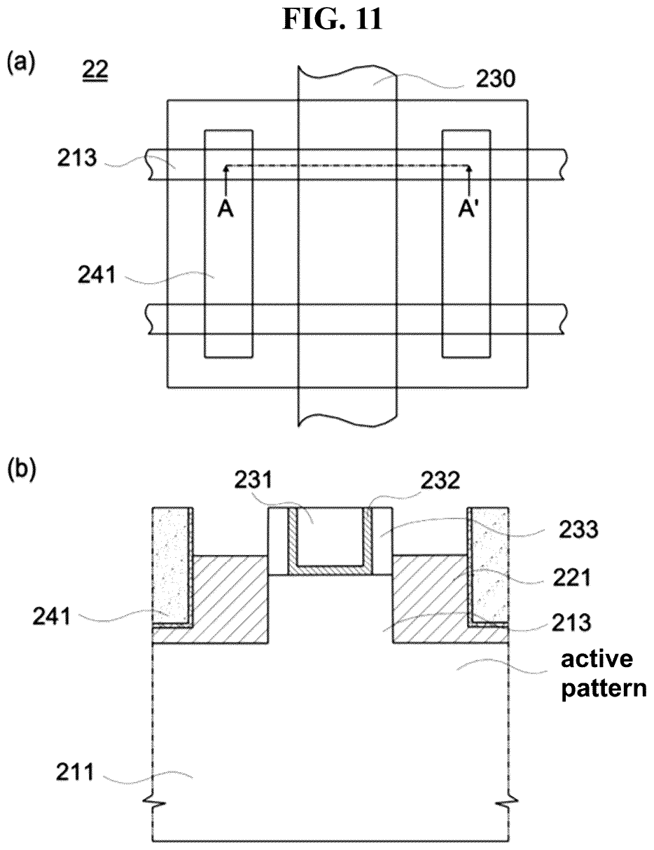

FIG. 11 is a layout view (a) and a cross-sectional view along line A-A′, illustrating another embodiment of the semiconductor device (22) of the present invention, comprising a fin-type active region and a contact structure. The semiconductor device of this embodiment comprises a substrate (211), a fin-type active region (213), a gate electrode (231), a gate dielectric film (232), source/drain regions (221), and a contact structure (241).

The substrate and the device isolation films may be substantially identical to those described in the explanation of FIG. 10. Active patterns are defined on the substrate by device isolation films (not shown), and in this embodiment, the substrate has a fin-type active region (213) protruding from the substrate and extending in a first direction from the active pattern of the substrate. When having multiple fin-type active regions, they may be arranged to be spaced apart at equal intervals. The device isolation films may be arranged to expose the upper portions of the active patterns, thereby defining the exposed upper portions of the active patterns as fin-type active regions.

As shown in FIG. 11(a), a gate structure (230) comprising the gate electrode (231) and gate dielectric film (232) is formed extending in a second direction intersecting the fin-type active region on the substrate. The gate structure may further comprise spacers (233). The gate electrode, gate dielectric film, and spacers may be substantially identical to those described in the explanation of FIG. 10. The gate structure may be formed to cover the fin-type active region. The fin-type active region disposed below the gate electrode acts as a channel region.

Source/drain regions (221) are disposed on each of the active patterns or fin-type active regions on both sides of the gate structure (230). A contact structure (241) is disposed to be electrically connected to the source/drain regions on both sides of the gate structure and may contact multiple source/drain regions. Further, the materials comprising the contact structure may be substantially identical to those described in the explanation of FIG. 10.

A high-k amorphous fluorinated carbon ultrathin film layer (251) having a dielectric constant of 10 or more with low leakage current density and high dielectric strength is formed at the interface between the source/drain regions (221) and the contact structure (241). Although the ultrathin film layer is composed of insulating material, it electrically connects the source/drain regions and the contact structure as it is formed as an atomic-scale ultrathin film.

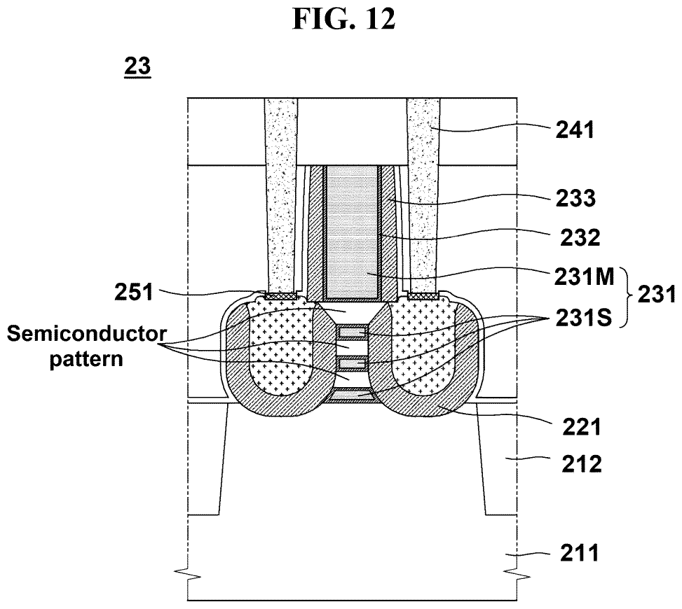

FIG. 12 is a cross-sectional view showing a semiconductor device according to another embodiment of the present invention. According to this embodiment, a semiconductor device (23) is provided comprising a substrate (211), a fin-type active region (213), semiconductor patterns, a gate electrode (231) including a main gate electrode (231M) and sub-gate electrodes (231S), a gate dielectric film (233), and source/drain regions (221).

The substrate, the device isolation films for defining the fin-type active region, and the fin-type active region may be substantially identical to those described in the explanation of FIGS. 10 and 11. In FIG. 12, while the upper surface of the device isolation films (212) is shown as being disposed at the same level as the upper surface of the fin-type active region, the device isolation films may be disposed at a lower level than the upper surface of the fin-type active region so that only the lower portion of the sidewalls of the fin-type active region may be surrounded by the device isolation films. The fin-type active region is formed protruding from the substrate and extends in a first direction. Multiple fin-type active regions may be formed.

The plurality of semiconductor patterns may be arranged spaced apart in a direction perpendicular to the top surface of the substrate (211) on the fin-type active region. The plurality of semiconductor patterns may comprise the same material as the substrate. For example, the plurality of semiconductor patterns may include semiconductors such as silicon or germanium, or compound semiconductors such as SiGe, SiC, GaAs, InAs, or InP. Further, each of the plurality of semiconductor patterns may include a channel region. In another embodiment, the plurality of semiconductor patterns may have, for example, a nanosheet shape.

The gate electrode (231) may extend over the fin-type active region and device isolation films while surrounding a plurality of semiconductor patterns. The gate electrode may include a main gate electrode (231M) and multiple sub-gate electrodes (231S). The main gate electrode may cover the upper surface of the uppermost semiconductor pattern, and the multiple sub-gate electrodes may be disposed between the fin-type active region and the lowermost semiconductor pattern, and between each of the plurality of semiconductor patterns.

A gate dielectric film (232) is interposed between the gate electrode (231) and the plurality of semiconductor patterns. Spacers (233) may be disposed on both sidewalls of the gate electrode. A gate dielectric film may be additionally interposed between the gate electrode and the spacers. The gate electrode, gate dielectric film, and spacers may be substantially identical to those described in the explanation of FIGS. 10 and 11.

Source/drain regions (221) are formed on both sides of the plurality of semiconductor patterns. The source/drain regions may be connected to both ends of the plurality of semiconductor patterns. While FIG. 12 shows the source/drain regions as being composed of two layers, it is not limited thereto and may be composed of a single layer or more than one layer.

The contact structures (241) are substantially identical to those described in the explanation of FIGS. 10 and 11 and is electrically connected to the source/drain regions. The contact structures may contact multiple source/drain regions.

In the semiconductor device of the present invention, ultrathin film layers (251) formed of high-k amorphous fluorinated carbon having a dielectric constant of 10 or more are interposed between the source/drain regions (221) and the contact structures (241). Although the ultrathin film layers are composed of insulating material, they enable electrical connection between the source/drain regions and the contact structures as they are formed as atomic-scale ultrathin films.

### DESCRIPTION OF THE SYMBOLS

10: Semiconductor structure
110: Semiconductor material layer 120: Metal material layer
130: Ultrathin film layer
21, 22, 23: Semiconductor device
211: Substrate 212: Device isolation film
213: Fin-type active region
221: Source/drain regions
230: Gate structure 231: Gate electrode
232: Gate dielectric film 233: Spacer
241: Contact structure 251: Ultrathin film layer

1. A semiconductor structure comprising:
a semiconductor material layer;
a metal material layer; and
an ultrathin film layer formed at the interface between the semiconductor material layer and the metal material layer, comprising amorphous fluorinated carbon having a dielectric constant of at least 10.

2. The semiconductor structure of claim 1, wherein the amorphous fluorinated carbon film further comprises hydrogen trapped in dangling bonds in the amorphous carbon film.

3. The semiconductor structure of claim 1, wherein the ultrathin film layer prevents Fermi level pinning phenomenon between the semiconductor material layer and the metal material layer.

4. The semiconductor structure of claim 1, wherein the ultrathin film layer suppresses dangling bonds in the semiconductor material layer.

5. The semiconductor structure of claim 1, wherein the ultrathin film layer has a leakage current of 10 A/cm² or less at an equivalent oxide thickness of 0.1 nm and an applied voltage of 1V.

6. The semiconductor structure of claim 5, wherein the ultrathin film layer has a dielectric strength of 10 MV/cm or more at an equivalent oxide thickness of 0.1 nm.

7. A method for manufacturing the semiconductor structure of claim 1, wherein the ultrathin film layer comprising amorphous fluorinated carbon having a dielectric constant of 10 or more is formed by:
(A) placing a substrate composed of a semiconductor material or a substrate having a semiconductor material layer formed thereon in a plasma reactor;
(B) introducing a first gas comprising fluorocarbon gas and a second gas comprising an inert gas into the reactor; and
(C) generating plasma in the reactor;
wherein at least one of the temperature of the reactor, pressure, flow rate of the first gas, flow rate of the second gas, and plasma intensity is controlled to grow an amorphous thin film having a dielectric constant of 10 or more.

8. A semiconductor device comprising source/drain regions and a contact structure electrically connected to the source/drain regions, wherein an amorphous fluorinated carbon ultrathin film layer having a dielectric constant of 10 or more is interposed between the source/drain regions and the contact structure.

9. The semiconductor device of claim 8, wherein the ultrathin film layer prevents Fermi level pinning phenomenon between the material constituting the source/drain regions and the material constituting the contact structure.

10. The semiconductor device of claim 8, wherein the ultrathin film layer suppresses dangling bonds in the material constituting the source/drain regions.

11. The semiconductor device of claim 8, comprising:
a substrate;
source/drain regions arranged facing each other on the substrate;
a gate electrode disposed on the substrate for applying an electric field;
a gate dielectric film interposed between the gate electrode and the substrate; and
a contact structure electrically connected to the source/drain regions.

12. The semiconductor device of claim 8, comprising:
a substrate;
a fin-type active region extending in a first direction on the substrate;
a gate structure extending in a second direction intersecting with the fin-type active region on the substrate, comprising a gate electrode and a gate dielectric film;
source/drain regions disposed on both sides of the gate structure; and
a contact structure electrically connected to the source/drain regions.

13. The semiconductor device of claim 8, comprising:
a substrate;
a fin-type active region protruding from the substrate and extending in a first direction;
a plurality of semiconductor patterns spaced apart from each other on the upper surface of the fin-type active region and having channel regions;
a gate electrode surrounding the plurality of semiconductor patterns and extending in a second direction perpendicular to the first direction, comprising a main gate electrode disposed at the uppermost part of the plurality of semiconductor patterns and extending in the second direction, and sub-gate electrodes disposed between the plurality of semiconductor patterns;
a gate dielectric film disposed between the gate electrode and the plurality of semiconductor patterns;
spacers disposed on both sidewalls of the main gate electrode;
source/drain regions disposed on both sides of the gate electrode, connected to the plurality of semiconductor patterns and in contact with the lower surface of the spacers; and
a contact structure electrically connected to the source/drain regions.
